(19) United States
(12) Patent Application Publication
(10) Pub. No.: US 2017/0365643 A1
(43) Pub. Date: Dec. 21, 2017

(54) PARALLEL CONFIGURED RESISTIVE MEMORY ELEMENTS

(71) Applicant: Altera Corporation, San Jose, CA (US)

(72) Inventors: Peter John McElheny, Morgan Hill, CA (US); Yue-Song He, San Jose, CA (US)

(21) Appl. No.: 15/186,137

(22) Filed: Jun. 17, 2016

(51) Int. Cl. H01L 27/24; H01L 45/00

(52) U.S. Cl. CPC H01L 27/2481; H01L 45/1675; H01L 27/2454; H01L 45/1233; H01L 45/1608

(57) ABSTRACT

The present invention discloses a memory cell that includes at least two non-volatile resistive memory elements coupled in parallel. The non-volatile resistive memory elements are capable of existing in different resistive states such that each of the different resistive state represents a different data state. The non-volatile resistive memory elements may include multiple layers formed within contact holes.

### BACKGROUND

The approaches described in this section could be pursued, but are not necessarily approaches that have been previously conceived or pursued. Therefore, unless otherwise indicated herein, the approaches described in this section are not prior art to the claims in this application and are not admitted to be prior art by inclusion in this section.

Integrated circuits often contain volatile memory elements. Typical volatile memory elements are based on cross-coupled inverters (latches). A volatile memory element retains data only so long as the integrated circuit is powered. In the event of power loss, the data in the volatile memory element is lost. For example, static random-access memory (SRAM) chips contain SRAM cells, which are a type of volatile memory element. Volatile memory elements are also used in programmable logic device integrated circuits.

Volatile memory elements are subject to a phenomenon known as soft error upset. Soft error upset events are caused by cosmic rays and radioactive impurities embedded in integrated circuits and their packages. Cosmic rays and radioactive impurities generate high-energy atomic particles such as neutrons and alpha particles. The memory elements contain transistors and other components that are formed from a patterned silicon substrate. When an atomic particle strikes the silicon in the memory element, electron-hole pairs are generated. The electron-hole pairs create a conduction path that can cause a charged node in the memory element to discharge and the state of the memory element to flip. If, for example, a “1” was stored in the memory element, a soft error upset event could cause the “1” to change to a “0.”

It is within this context that the embodiments herein arise.

### SUMMARY

Embodiments described herein include methods of initializing a memory device and an initialization apparatus. It should be appreciated that the embodiments can be implemented in numerous ways, such as a process, an apparatus, a system, a device, or a method. Several embodiments are described below.

In one embodiment, a memory cell is disclosed. The memory cell may include a first non-volatile resistive memory element. The memory cell may also include a second non-volatile resistive memory element coupled in parallel to the first non-volatile resistive memory element. In an embodiment, the first and second non-volatile resistive memory elements are capable of existing in first and second resistive states of a plurality of resistive states respectively, wherein each resistive state of the plurality of resistive states represents a different data state.

In another embodiment, a method of forming a memory cell is discussed. The method may include an operation to form an access transistor on a substrate. The method may also include an operation to deposit a first metal layer on the substrate. The method may further include an operation to deposit an inter-metal dielectric layer on the first metal layer. The method may include an operation to etch first and second contacts in the inter-metal dielectric layer. The method may then include an operation to deposit first and second bottom electrode in the first and second contact respectively. The method may include an operation to deposit first and second layer of oxide on the first and second bottom electrode respectively. The method may include an additional operation to deposit first and second top-electrode on the first and second layer of oxide respectively. The method may also include an operation to deposit a second metal layer on the first and second top electrode.

In yet another embodiment, an integrated circuit is disclosed. The integrated circuit may include a first memory cell comprising a first non-volatile resistive memory element and a second non-volatile resistive memory element coupled in parallel to the first non-volatile resistive memory element. The integrated circuit may also include a select transistor comprising a first source-drain terminal, wherein the first source-drain terminal is connected to the first memory cell. In another embodiment, a second memory cell is connected to a second source-drain terminal of the select transistor.

### BRIEF DESCRIPTION OF THE DRAWINGS

FIG. 1 illustrates an exemplary programmable logic device integrated circuit in accordance with an embodiment.

FIG. 2 illustrates a diagram of an exemplary memory array circuitry in accordance with an embodiment.

FIG. 3A illustrates a cross-sectional side view of an exemplary memory cell in accordance with an embodiment.

FIG. 3B illustrates a top view of an exemplary memory cell in accordance with an embodiment.

FIG. 4 illustrates a cross-sectional view of exemplary non-volatile resistive memory elements formed in a memory cell in accordance with an embodiment.

FIG. 5 illustrates an exemplary method of forming a memory cell in accordance with an embodiment.

FIG. 6 illustrates an exemplary graphical representation of the relationship between on-state resistance of a memory cell and a number of non-volatile resistive memory elements in the memory cell in accordance with an embodiment.

FIG. 7 illustrates an exemplary integrated circuit incorporating two memory cells in accordance with an embodiment of the present invention.

### DETAILED DESCRIPTION

Non-volatile memory elements can be used to circumvent the shortcomings of traditional volatile memory elements. Non-volatile memory elements can be implemented in a variety of ways in an integrated circuit. For example, resistive memory elements can be implemented. Resistive memory elements come in different varieties based on the process of manufacture and the resistive memory materials utilized during the process of manufacture. Some common types of resistive memory elements include anti-fuse type, ionic-displacement type, and magnetic type. However, non-volatile resistive memory elements usually have a very high SET resistance or on-state resistance. Thus, the resistive memory elements require high current for operation, which may be damaging to the other components of the integrated circuit. Furthermore, memory structures composed of resistive memory elements tend to have large variation across memory cells.

The present embodiments disclose memory cells composed of resistive memory elements that can be formed in integrated circuits such as programmable integrated circuits. The integrated circuits may be any suitable type of integrated circuit, such as microprocessors, application-specific integrated circuits, digital signal processors, memory circuits, or other integrated circuits. If desired, the integrated circuits may be programmable integrated circuits that contain programmable logic circuitry. The present invention will generally be described in the context of integrated circuits such as programmable logic device (PLD) integrated circuits as an example.

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present embodiments.

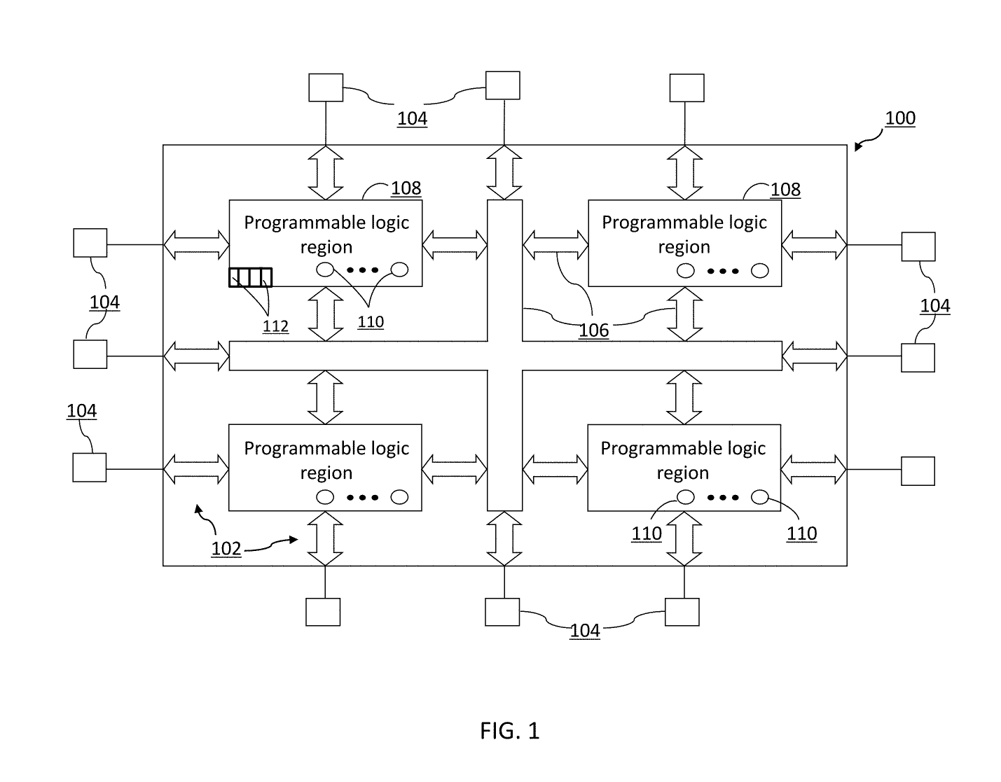

FIG. 1 illustrates a programmable logic device circuit in accordance with an embodiment of the present invention. In FIG. 1, programmable logic device (PLD) circuit 100 may include input-output circuitry 102 for driving signals of device circuit 100 and for receiving signals from other devices via input-output pins 104. Interconnect circuit 106 may comprise resources such as global and local vertical and horizontal conductive lines and buses may be used to route signals on PLD circuit 100. Interconnect circuit 106 includes conductive lines and programmable connections between respective conductive lines and are therefore sometimes referred to as programmable interconnects.

PLD circuit 100 may include programmable logic 108 that can be configured to perform a custom logic function. Programmable logic 108 may include combinational and sequential logic circuitry. Interconnect circuit 106 may be considered to be a type of programmable logic 108.

PLD circuit 100 may also contain programmable memory array 110. Memory array 110 can be loaded with configuration data (also called programming data) using pins 104 and input-output circuitry 102. Once loaded, the memory elements may each provide a corresponding static control signal that controls the operation of an associated logic component in programmable logic 108. In a typical scenario, the outputs of the loaded memory array 110 is applied to the gates of metal-oxide-semiconductor transistors in programmable logic 108 to turn certain transistors on or off and thereby configure the logic in programmable logic 108 and routing paths. Programmable logic circuit elements that may be controlled in this way include pass transistors, parts of multiplexers (e.g., multiplexers used for forming routing paths in interconnect circuit 108), look-up tables, logic arrays, various logic gates, etc.

Memory array 110 may be implemented using any suitable volatile and/or non-volatile memory structures such as random-access-memory (RAM) cells, fuses, antifuses, programmable read-only-memory memory cells, mask-programmed and laser-programmed structures, resistive memory structures, combinations of these structures, etc. Because memory array 110 is loaded with configuration data during programming, memory array 110 is sometimes referred to as configuration memory, configuration RAM (CRAM), or programmable memory elements.

The circuitry of PLD circuit 100 may be organized using any suitable architecture. As an example, the logic of PLD circuit 100 may be organized in a series of rows and columns of larger programmable logic regions each of which contains multiple smaller logic regions. The smaller regions may be, for example, regions of logic that are sometimes referred to as logic elements (LEs), each containing a look-up table (LUT), one or more registers, and programmable multiplexer circuitry. The smaller regions may also be, for example, regions of logic that are sometimes referred to as adaptive logic modules (ALMs). Each adaptive logic module may include a pair of adders, a pair of associated registers and a look-up table or other block of shared combinational logic (as an example). The larger regions may be, for example, logic array blocks (LABs) containing multiple logic elements or multiple ALMs. In the example of FIG. 1, illustrative logic regions 112 (which may be, for example, LEs or ALMs) are shown in one of the larger regions of programmable logic 108 in FIG. 1 (which may be, for example, a logic array block). In a typical PLD circuit 100, there may be hundreds or thousands of smaller logic regions 112. Logic regions 112 that are shown in FIG. 1 are merely illustrative.

During device programming, configuration data is loaded into PLD circuit 100 that may configure the programmable logic regions 112 and programmable logic regions 108 so that their logic resources perform desired logic functions on their inputs and produce desired output signals. For example, CRAM cells are loaded with appropriate configuration data bits to configure adders and other circuits on device 100 to implement desired custom logic designs.

The resources of PLD circuit 100 such as programmable logic regions 108 may be interconnected by interconnect circuit 106. Interconnect circuit 106 generally includes vertical and horizontal conductors. These conductors may include global conductive lines that span substantially all of device 100, fractional lines such as half-lines or quarter lines that span part of PLD circuit 100, staggered lines of a particular length (e.g., sufficient to interconnect several logic array blocks or other such logic areas), smaller local lines, or any other suitable interconnection resource arrangement. If desired, the logic of PLD circuit 100 may be arranged in more levels or layers in which multiple large regions are interconnected to form still larger portions of logic. Still other device arrangements may use logic that is not arranged in rows and columns.

In addition to the relatively large blocks of programmable logic that are shown in FIG. 1, PLD circuit 100 generally also includes some programmable logic associated with the programmable interconnects, memory, and input-output circuitry on PLD circuit 100. For example, input-output circuitry 102 may contain programmable input and output buffers. Interconnect circuit 106 may be programmed to route signals to a desired destination.

Embodiments of the present invention relate to integrated circuit memory array 110 that are resistant to soft error upset events. The memory array 110 can be used in any suitable integrated circuits that use memory. These integrated circuits may be memory chips, digital signal processing circuits with memory arrays, microprocessors, application specific integrated circuits with memory arrays, programmable integrated circuits such as programmable logic device integrated circuits in which memory array 110 is used for configuration memory, or any other suitable integrated circuit.

On integrated circuits such as memory chips or other circuits in which memory is needed to store processing data, memory array 110 may be volatile memory elements (e.g., random-access memory cells such as static random-access memory cells), nonvolatile memory elements (e.g., relay devices, fuses, antifuses, electrically-programmable read-only memory elements, etc.), or other types of memory elements. In the context of programmable integrated circuits, memory array 110 can be used to store configuration data and are therefore sometimes referred to in this context as configuration memory cells.

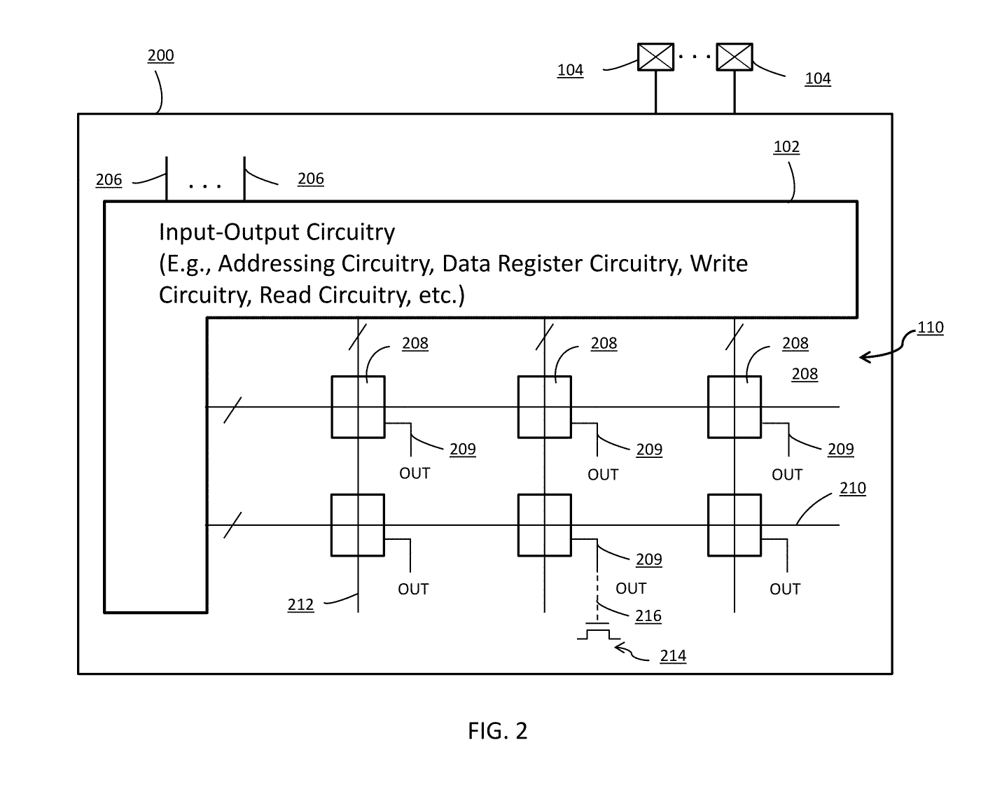

FIG. 2 shows an integrated circuit that may include memory array 110. Memory array 110 of FIG. 2 is comprised of memory cells 208 and for the purposes of illustrating clear examples, memory cells 208 forming memory array 110 will be discussed with reference to PLD circuit 100 of FIG. 1. Any suitable memory array architecture may be used for memory cells 208. One suitable arrangement is shown in FIG. 1. There are only two rows and three columns of memory cells 208 in the illustrative array of FIG. 1, but in general there may be hundreds or thousands of rows and columns in memory array 110. Memory array 110 may be one of a number of arrays on a given device 200, may be a subarray that is part of a larger array, or may be any other suitable group of memory cells 208.

Each memory array 110 may supply a corresponding output signal OUT at a corresponding output path 209. In configuration memory arrays, each signal OUT is a static output control signal that may be conveyed over a corresponding path 216 and may be used in configuring a corresponding transistor such as transistor 214 or other circuit element in an associated PLD circuit 100.

Integrated circuit 200 may have input-output circuitry 102 for supplying signals to memory array 110. Input-output circuitry 102 may receive power supply voltages, data, and other signals from external sources using pins 104 and from input-output circuitry 102 including paths such as paths 206. Input-output circuitry 102 may include circuitry such as addressing circuitry, data register circuitry, write circuitry, read circuitry, etc. Input-output circuitry 102 may use the power supply voltages supplied by pins 104 to produce desired time-varying and fixed signals on paths such as paths 210 and 212.

The signals that are supplied to memory array 110 may sometimes be collectively referred to as control signals. In particular contexts, some of these signals may be referred to as power signals, clear signals, data signals, address signals, etc. These different signal types are not mutually exclusive. For example, a clear signal for memory array 110 may serve as a type of control (address) signal that can be used to clear array 110. This clear signal may also serve as a type of power signal by powering inverter-like circuitry in cells 208. Likewise, because clearing operations serve to place logic zeros in memory cells 208, clear signals may serve as a type of data signal.

In general, there may be any suitable number of conductive lines associated with paths 210 and 212. For example, each row of memory array 110 may have associated address lines (e.g., a true address line and a complement address line) and associated read/write enable lines in a respective one of paths 210 (as examples). Each column of memory array 110 may have a respective path 212 that includes data lines. The terms “rows” and “columns” merely represent one way of referring to particular groups of cells 208 in memory array 110 and may sometimes be used interchangeably. If desired, other patterns of lines may be used in paths 210 and 212. For example, different numbers of power supply signals, data signals, and address signals may be used.

A clear signal may be routed to all of the memory cells 208 in memory array 110 simultaneously over a common clear line. The clear line may be oriented vertically so that there is one branch of the clear line in each path 212 or may be oriented horizontally so that there is one branch of the clear line in each path 210. The clear line need not be necessary.

Power can also be distributed in this type of global fashion. For example, a positive power supply voltage Vcc may be supplied in parallel to each cell 208 using a pattern of shared horizontal or vertical conductors. A ground voltage Vss may likewise be supplied in parallel to cells 208 using a pattern of shared horizontal or vertical lines. Control lines such as address lines and data lines are typically orthogonal to each other (e.g., address lines are vertical while data lines are horizontal or vice versa).

Positive power supply voltage Vcc may be provided over a positive power supply line. Ground voltage Vss may be provided over a ground power supply line. Any suitable values may be used for positive power supply voltage Vcc and ground voltage Vss. For example, positive power supply voltage Vcc may be 1.2 volts, 1.1 volts, 1.0 volts, 0.9 volts, less than 0.9 volts, or any other suitable voltage. Ground voltage Vss may be zero volts (as an example). In a typical arrangement, power supply voltages Vcc may be 1.0 volts, Vss may be zero volts, and the signal levels for address, data, and clear signals may range from zero volts (when low) to 1.0 volts (when high). Arrangements in which Vcc varies as a function of time, in which Vss is less than zero volts, and in which control signals are overdriven (i.e., in which control signals have signal strengths larger than Vcc−Vss) may also be used.

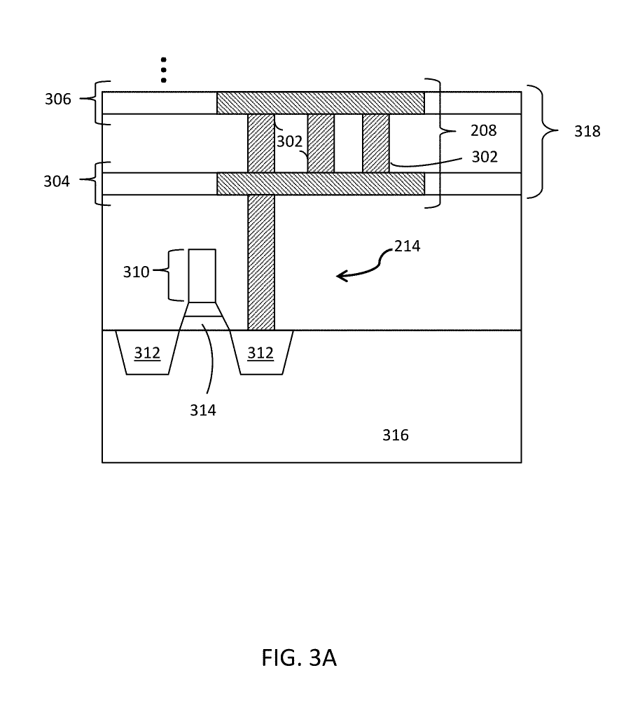

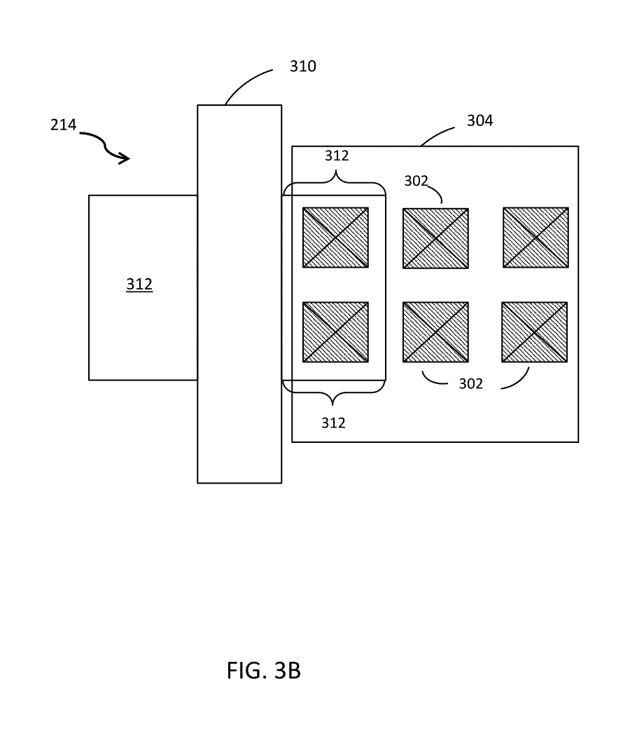

FIG. 3A illustrates a cross-sectional side view of an exemplary memory cell 208 in accordance with an embodiment of the present invention. For the purposes of illustrating clear examples, FIG. 3A will be discussed in reference to memory array 110 of FIG. 2. In an embodiment, the power supply lines discussed in FIG. 2 may be coupled to transistor 214. Transistor 214 may include source-drain regions (e.g., oxide definition regions) 312 separated by a channel region and a conductive gate structure 310 formed over the channel region. A layer of insulating material such as layer 314 of silicon oxide may be interposed between gate structure 310 and the surface of substrate 316 above the channel region. One of the source-drain terminals of transistor 214 may be coupled to time-varying power supply line through the contacts or contact holes containing resistive memory elements 302. A person skilled in the art will note that the number of resistive memory elements 302 (and by extension the number of contacts) is independent of the size of source-drain regions 312.

In an embodiment, the contacts or contact holes containing resistive memory elements 302 are long parallel structures that have widths that are at or greater than the minimum feature size for the manufacturing processes used to form the device. For example, current lithography and nano-imprint techniques may have minimum feature sizes that are on the order of 10 nanometers. Thus, if the contact holes containing resistive memory elements 302 were formed using a nano-imprint technique with a minimum feature size of 10 nanometers, the contact holes would have a width of 10 nanometers or more. Nano-imprinting is a method for fabricating nanometer scale patterns that is low cost, high throughput and high resolution. It creates patterns by mechanical deformation of the imprint resist. The imprint resist is typically a polymer formulation that is cured by heat or UV light during the imprinting. FIG. 3A illustrates contacts with a rectangular cross-section. In an embodiment, the contact holes may have a circular cross-section. In another embodiment, the edges of the metal layers are exposed to the contact holes.

Dielectric layer 318 may be formed over the surface of substrate 316. Dielectric layer 318 may include layers of silicon oxide or other dielectrics within which resistive memory elements 302 are formed. Dielectric layer 318 may include metal interconnect layers (sometimes referred to as metal layers or metal routing layers) and contacts for resistive memory elements 302. Conductive routing lines (sometimes referred to as metal interconnect paths) may be formed in the metal routing layers to electronically connect resistive memory elements 302 in parallel with each other. Contacts may also contain vertical conducting structures (e.g., conductive contacts such as tungsten contacts, copper contacts, aluminum contacts, or other metal contacts) configured to connect the conductive routing lines formed at opposing ends of each contact.

The metal routing layer closest to substrate 316 may be referred to as first metal routing layer 304. In an embodiment, there may be a number of successive metal routing layers. For example, first metal routing layer 304 represents a bottom layer in the dielectric stack, whereas a second metal routing layer 306 represents a top layer in the dielectric stack. Dielectric layer 318 may be configured in an alternating arrangement in which each adjacent pair of metal routing layers are separated by one or more resistive memory elements 302 formed in contacts. The implementation of the parallel connected resistive memory elements 302 is unaffected by either the size of the contact holes or the spacing between the metal layers. In the example of FIG.3, the time-varying power supply lines discussed above are formed in first metal routing layer 304. A person skilled in the art would recognize that the power supply lines might be formed in other metal routing layers, if desired. Similarly, resistive memory elements 302 may also be formed between different metal layers, if desired.

FIG. 3B illustrates a top view of an exemplary memory cell 208 in accordance with an embodiment of the present invention. Memory cell 208 in FIG. 3B includes six resistive memory elements 302 formed in dielectric layer 318 in contact with transistor 214 formed on substrate 316. Source-drain region 312 is separated by a channel region and a conductive gate structure 310 formed over the channel region. A person skilled in the art would note that the number of resistive memory elements 302 and the rectangular cross-section of the contacts varies among different implementations. Furthermore, the area of contact between transistor 214 and bottom metal layer 304 varies among implementations and is independent of the functioning of memory cell 208.

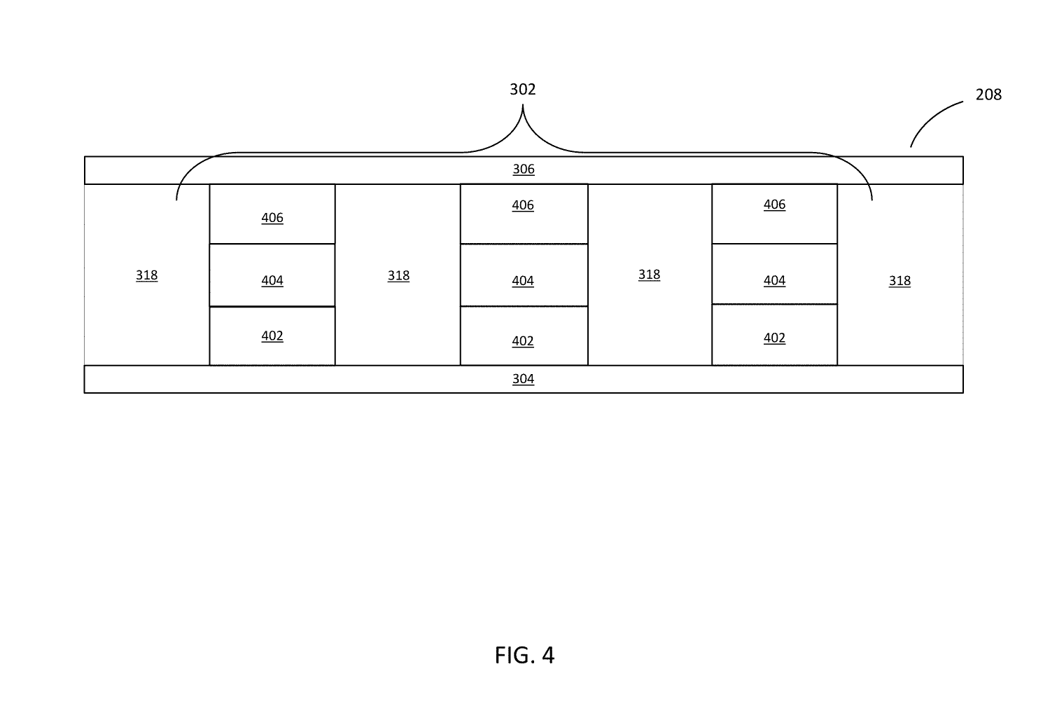

FIG. 4 illustrates a cross-sectional side view of an exemplary non-volatile resistive memory cell 208 in accordance with an embodiment of the present invention. For the purposes of illustrating clear examples, FIG. 4 will be discussed in reference to FIG. 3A and FIG. 3B. FIG. 4 illustrates a similar perspective of memory cell 208 as depicted in FIG. 3A and includes six resistive memory elements 302 (of which three are visible). However, a person having ordinary skill in the art will recognize that the number of resistive memory elements 302 will vary across implementations.

Resistive memory elements 302 may include two metal layers and are electronically connected in parallel with each other. For example in FIG. 4, resistive memory elements 302 include the first metal layer 304 and the second metal layer 306. In an embodiment, resistive memory elements 302 include first metal layer 304, bottom electrode layer 402, oxide layer 404, top electrode 406, and second metal layer 306. In another embodiment, resistive memory elements 302 may have additional layers. For example, oxide layer 404 may include one or more layers of oxides of different materials. Similarly, resistive memory elements 302 may include one or more non-ohmic layers with a metal-insulator-metal (MIM) arrangement.

First and second metal layers 304 and 306 respectively may be formed from any suitable material, including conductive metals (such as aluminum, copper, platinum, or tungsten), conductive polymers, conductive carbon based materials (such as diamond film, graphene, carbon nanotubes), or other suitable materials. Typically, top and bottom electrodes 402 and 406 respectively are commonly composed of platinum, gold, silver, or aluminum. In an embodiment, wherein electrodes 402 and 406 are used as a barrier to prevent metal inter-diffusion, then a thin layer of metal, e.g. titanium nitride (TiN), may be formed on electrodes during fabrication. If a seed layer is additionally required, any number of electrically conductive materials can be used for on top of the thin layer of metal. For example, the seed layer could be a conductive perovskite, such as LaNiO3 or SrRuO3 on platinum, a conductive metal oxide, such as IrO2 on iridium or RuO2 on ruthenium, a noble metal such as platinum on TiN. A person skilled in the art will appreciate that the choice of electrode layers 402 and 406 in combination with the oxide layer 404 may affect the properties of resistive memory elements 302. As such, the memory function is realized either by oxide layer 404 properties or by the interface between electrodes 402 or 406 and the oxide layer 404.

Oxide layer 404 may be composed of perovskites (such as Sr(Zr)TiO₃), transition metal oxides (such as NiO or TiO₂), chalcogenides (such as Ge₂Sb₂Te₅ or AgInSbTe), solid-state electrolytes (such as GeS, GeSe, Cu₂S), or and PCMO (Pr_{0.7}Ca_{0.3}MnO₃). In an embodiment, oxide layer 404 is composed of one or more layers of multi-resistive state materials. A person skilled in the art will appreciate that since resistive memory elements 302 function as programmable nonvolatile resistors, any material that uses trapped charges to modify or alter conductivity could be used in the contacts to form resistive memory elements 302.

For example, doping different materials (e.g., insulators, conductors, conductive oxides, and/or polymers), may create charge traps by substituting the dopant for crystalline elements and allow oxide layer 404 to function as a programmable nonvolatile resistor. Doping may also be used to create charge traps by interstitially introducing dopants into a crystalline structure. In addition, introducing separate physical clusters, or groups of atoms, into a crystalline structure may create charge traps as well. The resistance value of oxide layer 404 is dependent on its area and thickness as well as other properties, such as oxygen content, crystalline structure, and stoichiometry. Similarly, the voltage at which oxide layer 404 switches resistive states is also dependent upon the various properties of the material used to form oxide layer 404.

The contacts and the resistive memory elements are formed in a layer of inter-metal dielectric or dielectric layer 318. Dielectric layer 318 may be formed of boron and phosphorous doped silicon glass (BPSG), silicon dioxide (SiO2), or silicon nitride (Si₃N₄).

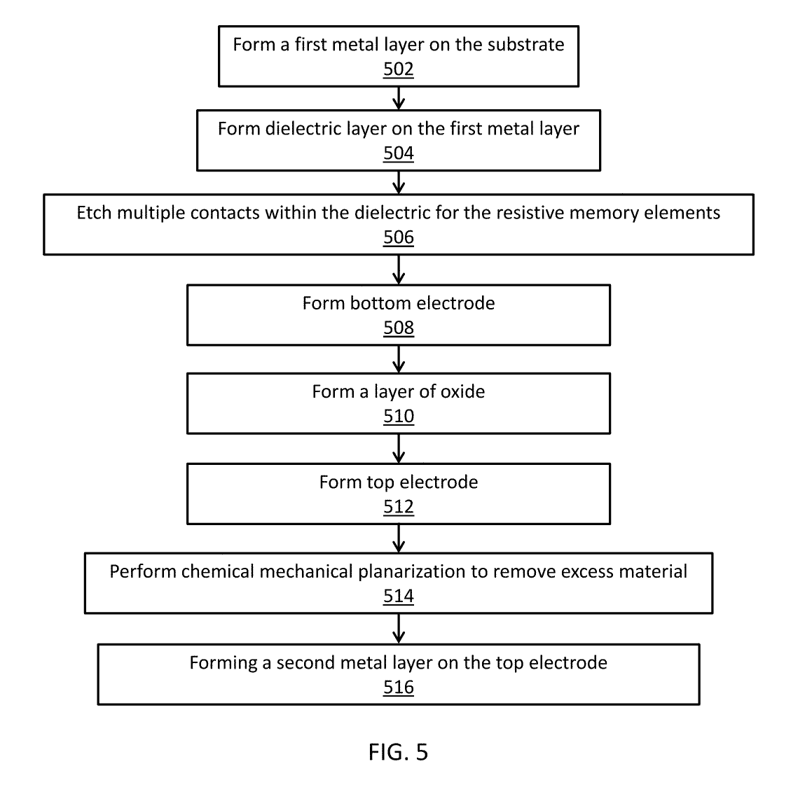

FIG. 5 illustrates an exemplary method of forming memory cell 208 in accordance with an embodiment of the present invention. For the purposes of illustrating clear examples, the method illustrated in FIG. 5 will be discussed in reference to memory cell 208 illustrated in FIGS. 3A, 3B, and 4. However, the same or a substantially similar method may be used for other implementations.

The fabrication process discussed in FIG. 5 may be preceded by front end of the line (FEOL) transistor formation on the circuit wafer. FEOL process FEOL contains all processes of semiconductor (for example complimentary metal-oxide semiconductor or CMOS) fabrication needed to form fully isolated semiconductor elements. The FEOL process may include selecting the type of wafer to be used, chemical-mechanical planarization (CMP) and cleaning of the wafer, shallow trench isolation (STI), well formation, gate module formation, and source and drain module formation. A person skilled in the art would appreciate that that each of the sub-processes of the FEOL process can be carried out using a wide variety of semiconductor fabrication techniques and methods.

Referring now to FIG. 5 again, at block 502, first metal layer 304 is formed on substrate 316. As discussed above, first metal layer 304 may be formed by depositing a suitable conductive metal for example copper or aluminum on the substrate. In another embodiment, the deposition of the metal layer is followed by forming conductive lines in first metal layer 304. In an embodiment, the deposition of conductive metal is followed by CMP to remove excess material. At block 504, di-electric layer 408 is formed on first metal layer 304. In an embodiment, dielectric layer 408 formed is an inter-metal dielectric. Dielectric layer 408 is formed by depositing a suitable insulator.

At block 506, a mask is applied to the wafer and the contact holes for resistive memory elements 302 are etched. In an embodiment, a photoresist or light-sensitive film is applied to the circuit wafer, giving it characteristics similar to a piece of photographic paper. A photo aligner aligns the wafer to the mask for etching contact holes for resistive memory elements 302 and then projects an intense light through the mask and through a series of reducing lenses, exposing the photoresist with the mask pattern. The exposed photoresist is then removed and baked to harden the remaining photoresist mask pattern. The wafer is then exposed to a chemical solution or plasma (gas discharge) so that areas not covered by the hardened photoresist are etched away. A person skilled in the art would appreciate that the contact holes for resistive memory elements 302 can be formed by utilizing many other techniques.

At block 508, resistive memory elements 302 are formed concurrently in the contact holes etched above. Bottom electrode 402 is formed in each of the contacts. At block 510, layer of oxide 404 is formed on bottom electrode 402. In an embodiment, forming layer of oxide 404 may include forming multiple layers of different oxides depending upon the fabrication specification. Layer of oxide 404 is the resistive memory material similar to the oxide layer described above. At block 512, top electrode 406 is formed on layer of oxide 404.

At block 514, chemical-mechanical planarization (CMP) is performed to remove access material deposited during the formation of memory cell 208. In an embodiment, CMP may also be performed following other deposition steps in the formation of memory cell 208. A person skilled in the art will appreciate that CMP may be performed via a variety of methods. At block 516, second metal layer 306 is formed on top electrode 406 connecting the multiple resistive memory elements 302 in parallel.

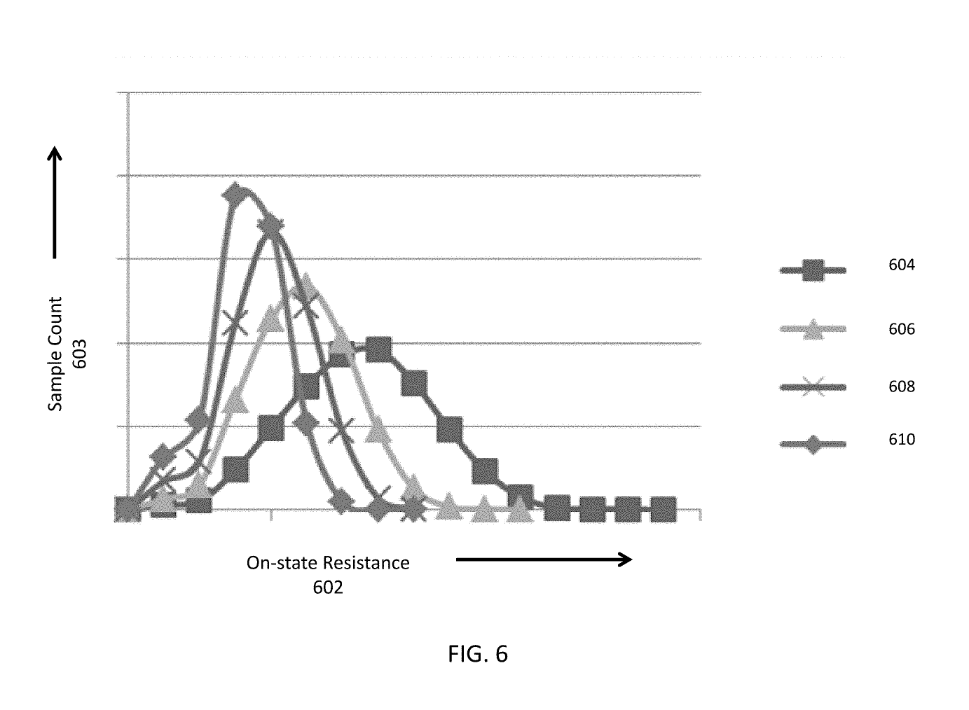

FIG. 6 illustrates an exemplary graphical representation of the relationship between the on-state or set resistance of a memory cell 208 and a number of non-volatile resistive memory elements 302 per memory cell in accordance with an embodiment of the present invention. For the purposes of illustrating clear examples, FIG. 6 will be discussed in reference to FIG. 4. Resistive memory elements 302 exhibit a non-volatile resistance value (a “state”). In some examples, resistive memory elements 302 can be used to store data, with the ON or low resistance state representing a digital 1 and an OFF or high resistance state representing a digital 0. In other implementations, resistive memory elements 302 may be part of multilevel cells that have more than two readable states.

Resistive memory elements 302 are programmed by applying a programming voltage (or “write voltage”) across resistive memory elements 302 electronically connected in parallel to each other. Since, the resistive memory elements are electronically connected in parallel to each other, once the lowest resistance resistive memory element out of resistive memory elements 302 acquires a resistance value (maybe referred to as SET value), the voltage across the remainder of resistive memory elements collapses. Thus, the final resistance value will be always determined by the first programmed, lowest resistance value. The application of the programming voltage causes a nonvolatile change in the electrical resistance of the resistive memory element, thereby changing its state.

The state of the memory element can be read by applying a read voltage. The read voltage has a lower magnitude than the write voltage and does not disturb the state of the resistive memory element. The state can be determined by reading the amount of a current that passes through the resistive memory element when the read voltage is applied. For example, if a relatively large amount of current flows through the resistive memory element, it can be determined that the resistive memory element is in a low resistance state. If a relatively small amount of current flows through the resistive memory element, it can be determined that the memory element is in a high resistance state.

FIG. 6 illustrates the effects on the SET resistance of a memory cell 208 with different combinations of resistive memory elements 302 electronically connected in parallel. The graphical curves represented by different symbols 604, 606, 608, and 610, represent the on-state resistance distribution for a single resistor, a memory cell containing three resistive memory elements, a memory cell containing four resistive memory elements, and a memory cell containing 12 resistive memory elements, respectively. The axis labeled 602 represents the on-state or set resistance for 604, 606, 608, and 610 increasing from left to right. The axis labeled 603 represents the number of samples for 604, 606, 608, and 610 were tested against. As is depicted by the distribution in the graph, resistive memory elements 302 electronically connected in parallel with each other lead to a tighter range for the on-state resistance and a lower mean for the SET resistance. In other words, on-state resistance is lower and less variable when using memory cells with multiple resistive memory elements 302. A person skilled in the art would appreciate that this can be explained because memory cell 208 is always set to the resistance value of the resistive memory element with the lowest resistance.

Memory cell 208 described above can be incorporated in a variety of circuit architectures to replace existing memory cell structures. For example, memory cell 208 may be utilized in a crossbar memory array as described in FIG. 2. Similarly, a combination of two memory cells and a select transistor may be used to replace a six transistor phase change random access memory (6T CRAM or 6T PCRAM).

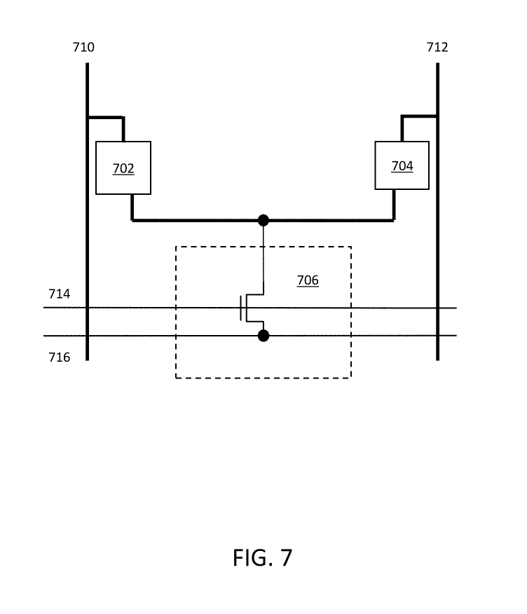

FIG. 7 illustrates an example integrated circuit incorporating two memory cells 702 and 704 in accordance with an embodiment of the present invention. For the purposes of illustrating clear examples, FIG. 7 will be discussed in reference to FIGS. 3A, 3B, and 4.

Referring now to FIG. 7, two memory cells 702 and 704 may be referred to as left and right memory cells respectively. Left memory cell 702 and right memory cell 704 are coupled to a shared select transistor 706. In an embodiment, bit lines 710 and 712 may be referred to as left bit line (LBL) and right bit line (RBL) respectively. LBL 710 and RBL 712 may be connected to programming voltages (or write voltages). The source-drain terminals of select transistor 706 are connected to a row-based signal (RS) 716. RS 716 may be connected to programming voltages or ground. To write a logic “1” to the memory structure of FIG. 7, left memory cell 702 is set to a low-resistance state. First, word line 714 is asserted and RS 716 is connected to ground. Then a suitable voltage (V_{SET}) is applied to LBL 710 while RBL 712 is left floating. Select transistor 706 limits the current as left memory cell 702 changes from high-resistance to low-resistance state. Similarly, to write 0 to right memory cell 704, right memory cell 704 is set to low-resistance state by floating LBL 710 and applying V_{SET} voltage to RBL 712.

Once written, the memory structure of FIG. 7 must be erased and restored to a fresh state (where both left memory cell 702 and right memory cell 704 are in high-resistance states) before opposite logic states can be written to each memory cell. The process of resetting the memory structure of FIG. 7 includes resetting each of the memory cells 702 and 704. First, LBL 710 is connected to ground and RBL 712 is left floating. After asserting word line 714, a reset voltage (V_{RST}) is applied to RS 716. Thus, a reset current flows to left memory cell 702. Similarly, to reset right memory cell 704, RBL 712 is grounded and LBL 710 is left floating and the process described above is repeated.

Both memory cells 702 and 704 can be read to verify the memory structure's logic state. The read process is similar to the resetting process. A read voltage (V_{RD}) is applied to RS 716 such that V_{RD}<V_{RST} and the bit line associated with the memory cell to be read is selected. The selected bit line is then connected to a mirror based sense amplifier that detects the resistance of the memory cell connected with the selected bit line.

In the foregoing specification, embodiments of the invention have been described with reference to numerous specific details that may vary from implementation to implementation. The specification and drawings are, accordingly, to be regarded in an illustrative rather than a restrictive sense. The sole and exclusive indicator of the scope of the invention, and what is intended by the applicants to be the scope of the invention, is the literal and equivalent scope of the set of claims that issue from this application, in the specific form in which such claims issue, including any subsequent correction. Any definitions expressly set forth herein for terms contained in such claims shall govern the meaning of such terms as used in the claims.

1. A memory cell comprising:
a first non-volatile resistive memory element that is formed in a first contact hole in a dielectric layer, wherein the dielectric layer is formed between first and second metal layers, wherein the first non-volatile resistor memory element comprises a top electrode layer that physically contacts the first metal layer, a bottom electrode layer that physically contacts the second metal layer, and an oxide layer that is interposed between the top and bottom electrode layers and that physically contacts the top and bottom electrode layers; and
a second non-volatile resistive memory element that is formed in a second contact hole in the dielectric layer and that is coupled in parallel to the first non-volatile resistive memory element.

2. The memory cell as defined in claim 1, wherein the first and second non-volatile resistive memory elements are capable of operating in first and second resistive states, and wherein each of the first and second resistive states represents a different data state.

3. (canceled)

4. (canceled)

5. (canceled)

6. The memory cell as defined in claim 1, wherein the first and second non-volatile resistive memory elements are connected in parallel by a plurality of conductive lines formed in the first and second metal layers.

7. The memory cell as defined in claim 1, wherein at least one of the first and second non-resistive memory elements is coupled to a source-drain region of a transistor.

8. The memory cell as defined in claim 1, wherein the memory cell is connected to at least a second memory cell in a memory array.

9-20. (canceled)

21. A memory cell comprising:
a first metal layer;
a second metal layer;
a contact hole that extends from the first metal layer to the second metal layer;
a non-volatile resistive memory element that is formed in the contact hole and that includes only three layers.

22. The memory cell of claim 21, wherein the only three layers of the non-volatile resistive memory element comprises:
a top electrode;
a bottom electrode; and
an oxide layer that is interposed between the top electrode and the bottom electrode.

23. The memory cell of claim 22, wherein the top electrode physically contacts the first metal layer.

24. The memory cell of claim 23, wherein the bottom electrode physically contacts the second metal layer.

25. The memory cell of claim 24, wherein the oxide layer physical contacts the top and bottom electrodes.
